(19) United States
(12) Patent Application Publication
(10) Pub. No.: US 2014/0117537 A1
(43) Pub. Date: May 1, 2014

(54) SEMICONDUCTOR PACKAGE AND METHOD OF FABRICATING THE SAME

(71) Applicant: SILICONWARE PRECISION INDUSTRIES CO., LTD., Taichung (TW)

(72) Inventors: Chen-Han Lin, Taichung (TW); Kuo-Hsiang Li, Taichung (TW); Jung-Pang Huang, Taichung (TW); Nan-Jia Huang, Taichung (TW); Hsin-Yi Liao, Taichung (TW)

(73) Assignee: SILICONWARE PRECISION INDUSTRIES CO., LTD., Taichung (TW)

(21) Appl. No.: 13/729,759

(22) Filed: Dec. 28, 2012

(30) Foreign Application Priority Data
Oct. 25, 2012 (TW) 101139426

(51) Int. Cl. H01L 23/498; H01L 21/56

(52) U.S. Cl. CPC H01L 23/49811; H01L 21/56
USPC 257/737; 438/127

(57) ABSTRACT

Disclosed is a semiconductor package including an encapsulant having a top surface and a bottom surface opposite to the top surface; a semiconductor chip embedded in the encapsulant having an active surface, an inactive surface opposite to the active surface, and lateral surfaces interconnecting the active surface and the inactive surface, wherein the active surface protrudes from the bottom surface of the encapsulant and the semiconductor chip further has a plurality of electrode pads disposed on the active surface; a positioning member layer formed on a portion of the bottom surface of the encapsulant, covering the lateral surfaces of the semiconductor chip that protrude therefrom, and exposing the active surface; and a build-up trace structure disposed on the active surface of the semiconductor chip and the positioning member layer formed on the bottom surface of the encapsulant. The present invention also provides a method of fabricating a semiconductor package.

### BACKGROUND OF THE INVENTION

1. Field of the Invention

This invention relates to semiconductor packages and methods of fabricating the same, and more particularly, to a semiconductor package that can resolve a die shift problem and a method of fabricating the semiconductor package.

2. Description of Related Art

With the rapid development of semiconductor technology, there are various types of semiconductor package products to meet application requirements. In order to fabricate compact-sized and low-profiled semiconductor packages, a WL-CSP (wafer level chip scale package) has been developed to provide a surface area large enough to carry a sufficient number of I/O (input/output) terminals and to utilize RDL (redistribution layer) technology to form an RDL on a semiconductor chip such that a plurality of bonding pads on the semiconductor chip are then redistributed via the RDL to the designed optimal positions as I/O (input/output) terminals.

However, in a method of fabricating such a package, the semiconductor chip is disposed on a carrier via a colloid, in order to simplify the processing steps and increase product yield. Referring to FIGS. 1A-1D, cross-sectional diagrams illustrating a method of fabricating a WS-CSP according to the prior art are provided.

As shown in FIG. 1A, a hot-off tape 101 is attached to a carrier 10, and a semiconductor chip having a plurality of electrode pads 110 is disposed at a predetermined position A on the hot-off tape 101.

As shown in FIG. 1B, a heated compressed film 12 is compressed by a compressing machine on the carrier 10 and the hot-off tape 101. The compressed film 12 encapsulates the semiconductor chip 11.

As shown in FIG. 1C, the carrier 10 and the hot-off tape 101 are removed to expose semiconductor chip 11 and the compressed film 12. As shown in FIG. 1D, a redistribution layer 15 that has a dielectric layer 151, a trace layer 152, and a protection film 153 is formed on the semiconductor chip 11 and the compressed film 12, and a plurality of buried conductive vias 150 formed on the redistribution layer 15 is electrically connected to the electrode pads 110 and the trace layer 152. However, as shown at the left-hand side of FIG. 1D, the compressed film 12 heated and compressed by the compressing machine will cause the semiconductor chip (or die) 11 to be shifted from the predetermined position A. As a result, the buried conductive vias 150 are not electrically connected to the electrode pads 110 and the trace layer 152 effectively, and product yield thus becomes lower.

Therefore, it is an urgent issue in the art to provide a semiconductor package and a method of fabricating the same, in which buried conductive vias are electrically connected to electrode pads perfectly.

### SUMMARY OF THE INVENTION

The present invention provides a semiconductor package, including an encapsulant having a top surface and a bottom surface opposite to the top surface; at least a semiconductor chip embedded in the encapsulant and having an active surface, an inactive surface opposite to the active surface, and lateral surfaces interconnecting the inactive surface and the active surface, wherein the active surface protrudes from the bottom surface of the encapsulant and the semiconductor chip further has a plurality of electrode pads on the active surface; a positioning member layer formed on a portion of the bottom surface of the encapsulant, covering the lateral surfaces of the semiconductor chip that protrude therefrom, and exposing the active surface; and a build-up trace structure formed on the active surface of the semiconductor chip and the positioning member layer formed on the bottom surface of the encapsulant.

The present invention further provides a method of fabricating a semiconductor package, including steps of providing a carrier having a surface formed with at least a semiconductor chip, wherein the semiconductor chip has an active surface, an inactive surface opposite to the active surface, and lateral surfaces interconnecting the active surface and the inactive surface, and the active surface is attached to the carrier via a soft material layer; forming a positioning member layer at an intersection of the active surface and the carrier, to cover a portion of the lateral surfaces of the semiconductor chip; forming an encapsulant on the positioning member layer and the semiconductor chip to embed semiconductor chip therein, wherein the encapsulant has a top surface and a bottom surface opposite to the top surface and is located at the same side as the soft material layer;

removing the carrier and the soft material layer to expose the active surface of the semiconductor chip and the positioning member layer; and forming a build-up trace structure on the active surface of the semiconductor chip and the positioning member layer.

Compared with the prior art, the method of fabricating a semiconductor package according to the present invention performs a thermal compression process after the semiconductor chip is wrapped by the positioning member layer. Therefore, the die shift problem of the semiconductor chip is limited by the positioning member layer, and the alignment accuracy of subsequent processes is improved significantly.

In the embodiment, before the carrier and the soft material layer are removed, a supporting layer is further formed on the top surface of the encapsulant, such that the encapsulant is encapsulated between the supporting layer and the positioning member layer to prevent the package from warpage.

### BRIEF DESCRIPTION OF DRAWINGS

The invention can be more fully understood by reading the following detailed description of the preferred embodiments, with reference made to the accompanying drawings, wherein:

FIGS. 1A-1D are cross-sectional diagrams illustrating a method of fabricating a WS-CSP according to the prior art;

FIGS. 2A-2F′ are cross-sectional diagrams illustrating a method of fabricating a semiconductor package in accordance with the present invention, wherein FIGS. 2B′ and 2B″ are cross-sectional diagrams illustrating another method of fabricating a semiconductor package in accordance with the present invention, and FIGS. 2E′ and 2F′ illustrate a method of fabricating a semiconductor package, in which no supporting layer is formed on a top surface of an encapsulant;

FIGS. 3-3″ are cross-sectional diagrams of a semiconductor package in accordance with one embodiment of the present invention, wherein FIG. 3′ is a cross-sectional diagram illustrating that a positioning member layer is formed on the whole bottom surface of an encapsulant, and FIG. 3″ is a cross-sectional diagram illustrating that the positioning member layer is formed only around at an intersection between an active surface of a semiconductor chip and a carrier;

FIGS. 4-4″ are cross-sectional diagrams of a semiconductor package in accordance with another embodiment of the present invention, wherein FIG. 4′ is a cross-sectional diagram illustrating that a positioning member layer is formed on the whole bottom surface of an encapsulant, and FIG. 4″ is a cross-sectional diagram illustrating that the positioning member layer is formed only at an intersection between an active surface of a semiconductor chip and a carrier;

FIG. 5 is a top view of a portion of a semiconductor package in accordance with one embodiment of the present invention; and

FIG. 6 is a top view of a portion of a semiconductor package in accordance with another embodiment of the present invention.

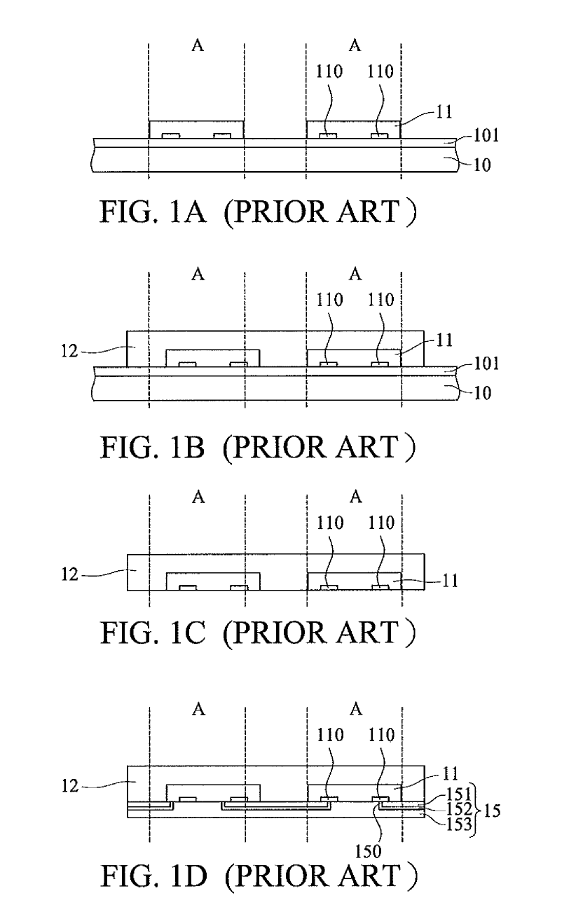

### DETAILED DESCRIPTION OF THE INVENTION

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

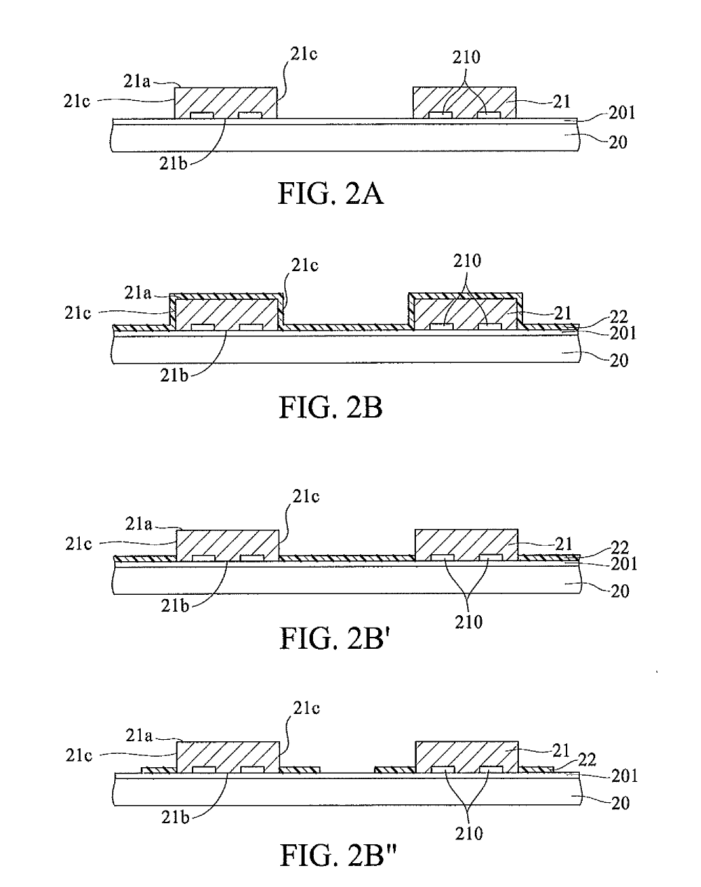

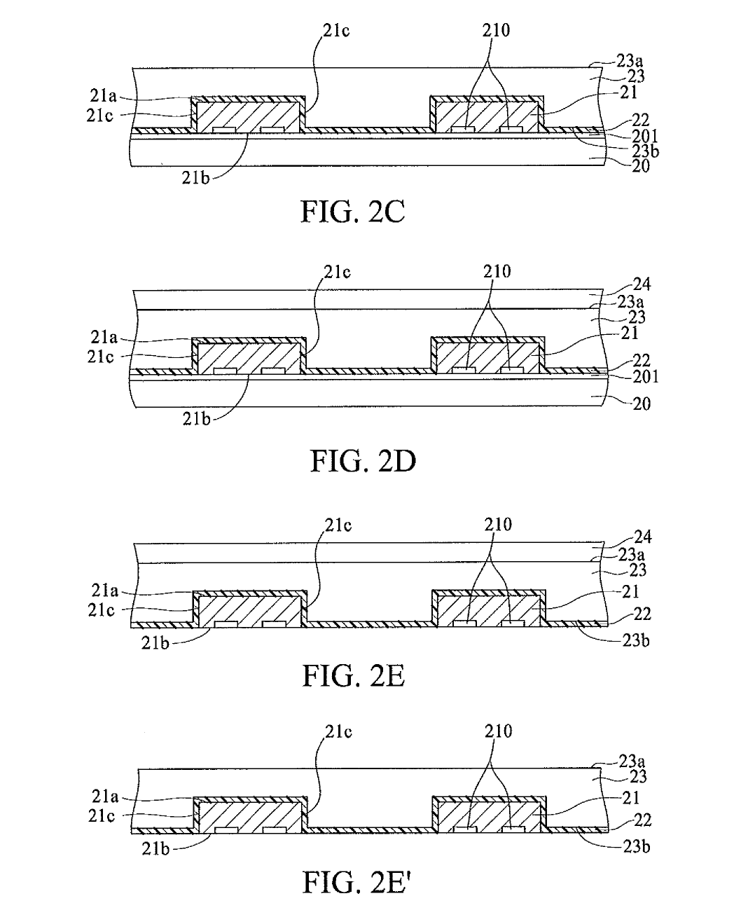

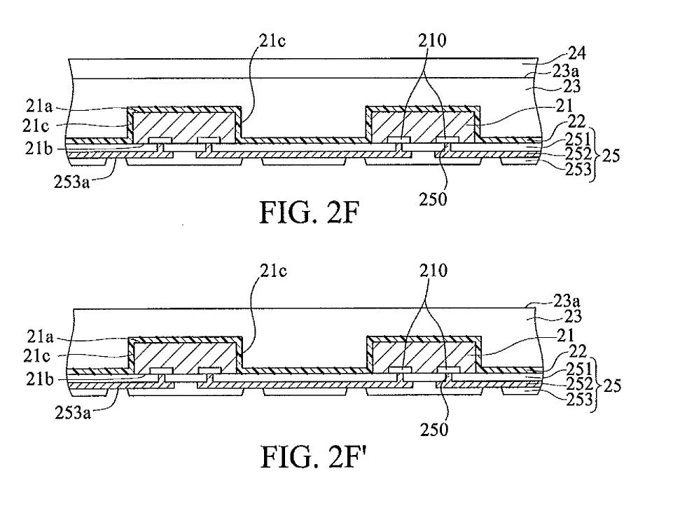

Referring to FIGS. 2A-2F′, cross-sectional diagrams illustrating a method of fabricating a semiconductor package in accordance with one embodiment of the present invention are provided.

Referring to FIG. 2A, a carrier 20 has a surface formed with at least a semiconductor chip 21. The semiconductor chip 21 has an active surface 21b, and an inactive surface 21a opposite to the active surface 21a. The active surface 21b of the semiconductor chip 21 is attached to the carrier 20 via a soft material layer 201. In an embodiment, the soft material layer 201 is formed completely on the carrier, and is a release film or tape. The semiconductor chip 21 further has a plurality of electrode pads 210 on the active surface 21b. In an embodiment, the carrier 20 is made of copper, metal, or silicon.

Referring to FIG. 2B, a positioning member layer 22 is formed on a surface of the semiconductor chip 21 and the soft material layer 201. In an embodiment, the positioning member layer 22 is a low-temperature resist and is made of a polymer material such as polyimide, epoxy resin or benzocyclobutene polymer. In an embodiment, the positioning member layer 22 is formed by spraying the low-temperature resist to the inactive surface 21a, the lateral surfaces 21c of the semiconductor chip 21 and the soft material layer 201, baked and cured at a low temperature of 90° C. Compared with the prior art, which forms the hot-off tape 101 at 130° C., the present invention does not affect the original fabrication process and thus increases product yield.

Please refer to FIG. 2B′. In an embodiment, the soft material layer 201 is formed on the whole surface of the carrier 20, and the positioning member layer 22, which is formed on the soft material layer 201 by spraying the low-temperature resist, and covers a portion of the lateral surfaces 21a around an intersection of the soft material layer 201 and the active surface of the semiconductor chip 21. Therefore, the positioning member layer 22 is formed on a portion of the surface of the carrier 20 on which the semiconductor chip is not formed. The low-temperature resist is baked and cured at 90° C., to form the positioning member layer 22.

Refer to FIG. 2B″. In another embodiment, the low-temperature resist is sprayed on a portion of the lateral surfaces 21c around an intersection of the active surface 21b of the semiconductor chip 21 and the soft material layer 201, so as to cover a portion of the soft material layer 201 that intersects with the active surface 21b of the semiconductor chip 21, and expose another portion of the soft material layer 201 that is not formed with the semiconductor chip 21. Then, the low-temperature resist is also baked and cured at 90° C. to form the positioning member layer 22.

Please refer to FIG. 2C, which follows the fabrication process shown in FIG. 2B. An encapsulant 23 is formed on the positioning member layer 22 and the semiconductor chip 21, and the semiconductor chip 21 is embedded in the encapsulant 23. The encapsulant 23 has a top surface 23a and a bottom surface 23b opposite to the top surface 23a and at the same side as the soft material layer 201. In an embodiment, the encapsulant 23 is made of the material selected from silicon resin (polymerized siloxanes, silicone or polysiloxanes), silicon oxide, ajinomoto build-up film (ABF), benzocyclobutenes (BCB), polyimide (PI), epoxide, and an organic dielectric layer material (SiLK™).

In another embodiment shown in FIG. 2D, a supporting layer 24 is further formed on the top surface 23a of the encapsulant 23, and the encapsulant 23 is encapsulated between the supporting layer 24 and the positioning member layer 22. In an embodiment, the supporting layer 24 is made of the material selected from silicon, glass, semiconductor-on-insulator (SOI), gallium arsenide (GaAs), indium arsenide (InAs), crystal and sapphire. The supporting layer 24 improves the stability of the package and prevents the package from warpage.

Referring to FIG. 2E, another embodiment of FIG. 2D is illustrated. The carrier 20 and the soft material layer 201 are removed by mechanical and/or chemical methods to expose the positioning member layer 22 formed on the bottom surface 23b of the encapsulant 23, and the active surface 21b of the semiconductor chip 21.

Referring to FIG. 2E′, the steps following FIG. 2C are shown. The carrier 20 and the soft material layer 201 are removed, and the active surface 21b of the semiconductor chip 21 and the positioning member layer 22 formed on the bottom surface 23b of the encapsulant 23 are exposed.

Referring to FIG. 2F, a build-up trace structure 25 is formed on the active surface 21b of the semiconductor chip 21 and the positioning member layer 22.

Referring to FIG. 2F′, it is shown that the supporting layer 24 is removed or the supporting layer 24 is not formed. The build-up trace structure 25 is formed on the active surface 21b of the semiconductor chip 21 and the positioning member layer 22. Furthermore, in the build-up trace structure 25 shown in FIGS. 2F and 2F′, a build-up trace layer 252 is formed on a dielectric layer 251, a solder mask 253 is formed on the build-up trace layer 252 to expose conductive pads 253a of the build-up trace layer 252, and a plurality of buried conductive vias 250 are formed in the dielectric layer 251 and electrically connected to the build-up trace layer 252 and the electrode pads 210. In an embodiment, the dielectric layer 251 is made of the material selected from oxide, nitride, un-doped silicate glass (USG), fluorinated silicate glass (FSG) and a low dielectric constant material.

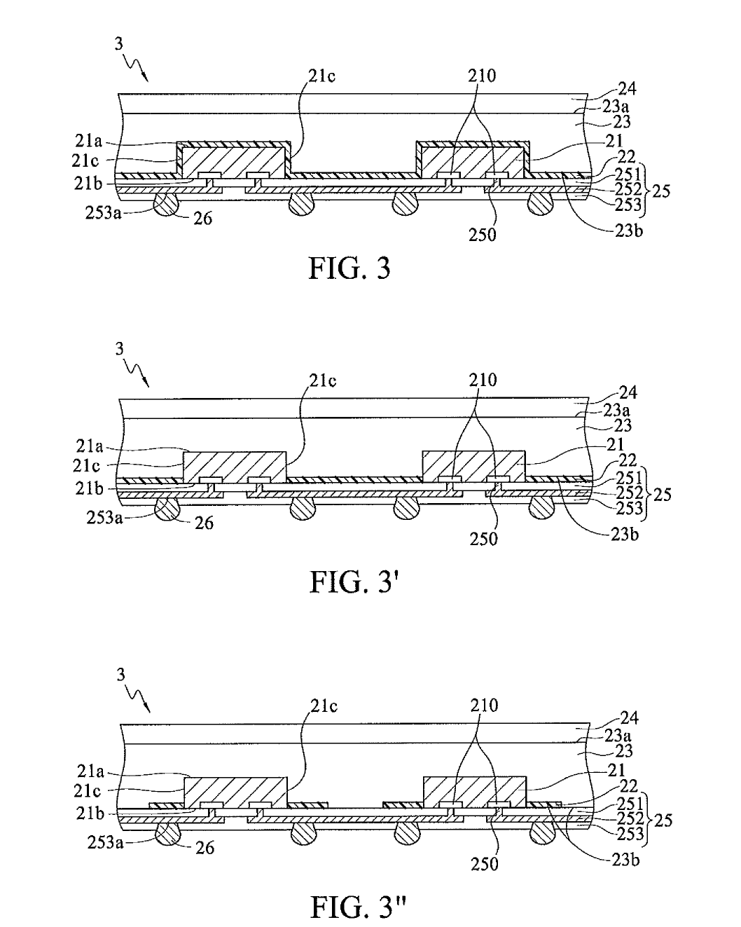

As shown in FIG. 3, conductive elements 26 such as solder bumps are formed on the conductive pads 253a of the build-up trace structure 25.

A singulation process is performed to obtain a plurality of semiconductor packages of the present invention, wherein each of the semiconductor packages has at least one semiconductor chip 21.

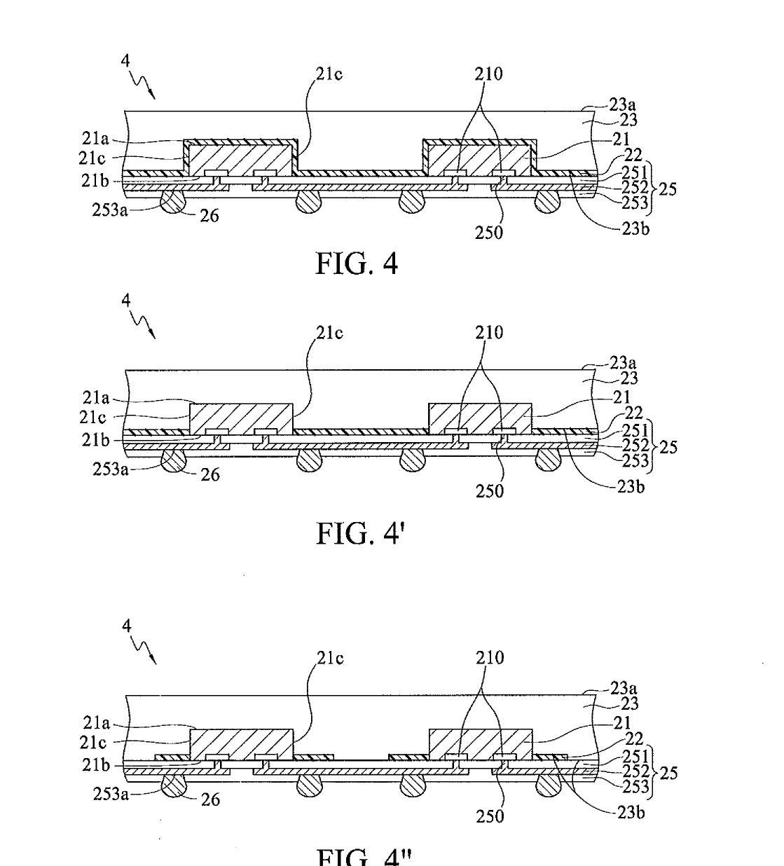

Referring to FIGS. 3 and 4, cross-sectional diagrams illustrating the application of a semiconductor package in accordance with the present invention are provided.

As shown in FIGS. 3 and 3″, the present invention provides a semiconductor package 3, including an encapsulant 23 having a top surface 23a and a bottom surface 23b opposite to the top surface 23a; a supporting layer 24 formed on the top surface 23a of the encapsulant 23; at least a semiconductor chip 21 embedded in the encapsulant 23 and having an active surface 21b and an inactive surface 21a opposite to the active surface 21b, and lateral surfaces 21c interconnecting the inactive surface 21a and the active surface 21b, wherein a plurality of electrode pads 210 are formed on the active surface 21b, and the active surface 21b of the semiconductor chip 21 protrudes from the bottom surface 23b of the encapsulant 23; a positioning member layer 22 formed between the semiconductor chip 21 and the encapsulant 23, extending and covering the bottom surface 23b of the encapsulant 23; and a build-up trace structure 25 formed on the active surface 21b of the semiconductor chip 21 and the positioning member layer 22 formed on the bottom surface 23b of the encapsulant 23. The build-up trace structure 25 includes at least a dielectric layer 251, a build-up trace layer 252 formed on the dielectric layer 251, a solder mask 253 formed on the build-up trace layer 252 that exposes conductive pads 253a of the build-up trace layer 252, and a plurality of buried conductive vias 250 formed in the dielectric layer 251 and electrically connected to the build-up trace layer 252 and the electrode pads 210. As shown in FIG. 3′, the positioning member layer 22 is formed on the whole bottom surface 23b of the encapsulant 23. As shown in FIG. 3″, the positioning member layer 22 is formed on a portion of the bottom surface 23b of the encapsulant 23 and covers a portion of the lateral surfaces 21c of the semiconductor chip 21 that protrude from the bottom surface 23b of the encapsulant 23. As shown in FIG. 3″, the build-up trace structure 25 is further formed on the bottom surface 23b of the encapsulant 23.

FIGS. 4-4″ are cross-sectional diagrams of a semiconductor package in accordance with another embodiment of the present invention. In a semiconductor package 4, as shown in FIG. 4′, the positioning member layer 22 is formed on the whole bottom surface 23b of the encapsulant 23. As shown in FIG. 4″, the positioning member layer 22 is formed on a portion of the bottom surface 23b of the encapsulant 23 and covers a portion of the lateral surfaces 21c of the semiconductor chip 21 that protrude from the bottom surface 23b of the encapsulant 23. As shown in FIG. 4″, the build-up trace structure 25 is further formed on the bottom surface 23b of the encapsulant 23.

In an embodiment, a conductive material used in the present invention may be, but not limited to, copper, aluminum, tungsten, silver, or a combination thereof.

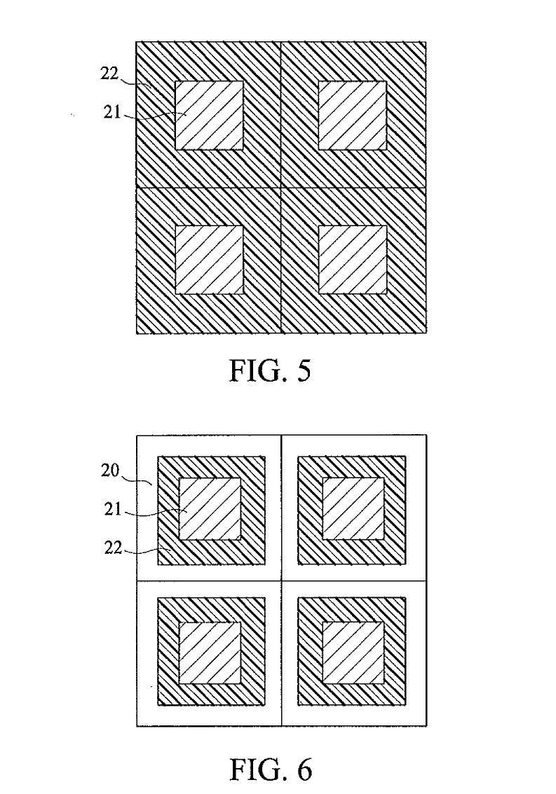

Referring to FIGS. 5 and 6, top views of a portion of the application of a semiconductor package in accordance with the present invention are provided.

In an embodiment shown in FIG. 5, the positioning member layer 22 is formed on the whole bottom surface, and only the semiconductor chip 21 is exposed.

As shown in FIG. 6, the positioning member layer 22 is formed only around an intersection of the semiconductor chip 21 and the carrier 20. It is thus known that the positioning member layer 22 can secure the semiconductor chip 21 to the designed site effectively such that there would be no die shift phenomenon in the subsequent processes.

In a semiconductor package and a method of fabricating the same in accordance with the present invention, before the encapsulant is formed, a layer of polymer is applied, baked and cured to form a positioning member layer that secures the semiconductor chip formed on the carrier and the soft material layer to the designed site. Therefore, the problem of the prior art that a semiconductor chip (or die) is shifted away during a thermal compression process by using a hot-off tape is alleviated, alignment accuracy of subsequent processes is improved significantly, and product yield becomes higher. The present invention further provides another semiconductor package and another method of fabricating the same, wherein a supporting layer is formed on a top surface of an encapsulant, and, as a result, the encapsulant is encapsulated between the supporting layer and the positioning member layer. Therefore, the warpage of the package is avoided.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A semiconductor package, comprising:
an encapsulant having a top surface and a bottom surface opposite to the top surface;
at least a semiconductor chip embedded in the encapsulant and having an active surface, an inactive surface opposite to the active surface, and lateral surfaces interconnecting the inactive surface and the active surface, wherein the active surface protrudes from the bottom surface of the encapsulant, and the semiconductor chip further has a plurality of electrode pads on the active surface;
a positioning member layer formed on a portion of the bottom surface of the encapsulant, covering the lateral surfaces of the semiconductor chip that protrude therefrom, and exposing the active surface; and
a build-up trace structure formed on both the active surface of the semiconductor chip and the positioning member layer formed on the bottom surface of the encapsulant.

2. The semiconductor package of claim 1, wherein the positioning member layer is formed on whole the bottom surface of the encapsulant.

3. The semiconductor package of claim 2, wherein the positioning member layer further extends over a region between the semiconductor chip and the encapsulant.

4. The semiconductor package of claim 1, wherein the positioning member layer further extends over a region between the semiconductor chip and the encapsulant.

5. The semiconductor package of claim 1, wherein the build-up trace structure includes at least a dielectric layer, a build-up trace layer formed on the dielectric layer, a solder mask formed on the build-up trace layer, and a plurality of buried conductive vias formed in the dielectric layer and electrically connected to the build-up trace layer and the electrode pads.

6. The semiconductor package of claim 1, wherein the build-up trace trace structure is further formed on the bottom surface of the encapsulant.

7. The semiconductor package of claim 1, wherein the build-up trace structure further has a plurality of conductive pads exposed therefrom.

8. The semiconductor package of claim 7, further comprising a plurality of conductive bumps formed on the conductive pads.

9. The semiconductor package of claim 1, further comprising a supporting layer formed on the top surface of the encapsulant.

10. The semiconductor package of claim 9, wherein the supporting layer is selected from the group consisting of silicon, glass, gallium arsenide, indium arsenide, crystal, sapphire, and a semiconductor-on-insulator.

11. The semiconductor package of claim 1, wherein the positioning member layer is made of a polymer material.

12. The semiconductor package of claim 11, wherein the polymer material is polyimide, epoxy resin, or benzocyclobutene polymer.

13. The semiconductor package of claim 1, wherein the encapsulant is made of a material selected from ajinomoto build-up film (ABF), polyimide, silicon resin, silicon oxide, epoxide and benzocyclobutenes (BCB).

14. A method of fabricating a semiconductor package, comprising steps of:
providing a carrier having a surface formed with at least a semiconductor chip, wherein the semiconductor chip has an active surface, an inactive surface opposite to the active surface, and lateral surfaces interconnecting the active surface and the inactive surface, and the active surface of the semiconductor chip is formed on the carrier via a soft material layer;
forming a positioning member layer around an intersection of the active surface of the semiconductor chip and the carrier, to cover a portion of the lateral surfaces of the semiconductor chip;
forming an encapsulant on the positioning member layer and the semiconductor chip to embed semiconductor chip therein, wherein the encapsulant has a top surface, and a bottom surface opposite to the top surface and located at the same side as the soft material layer;
removing the carrier and the soft material layer to expose the active surface of the semiconductor chip and the positioning member layer formed on the bottom surface of the encapsulant; and
forming a build-up trace structure on the active surface of the semiconductor chip and the positioning member layer.

15. The method of claim 14, wherein the positioning member layer is further formed on the inactive surface and the lateral surfaces of the semiconductor chip.

16. The method of claim 14, wherein the positioning member layer is formed on a portion of the surface of the carrier on which the semiconductor chip is not formed.

17. The method of claim 14, wherein the build-up trace structure is further formed on the bottom surface of the encapsulant.

18. The method of claim 14, further comprising a step of baking the positioning member layer prior to forming the encapsulant.

19. The method of claim 14, further comprising a step of: prior to removing the carrier and the soft material layer, forming a supporting layer on the top surface of the encapsulant such that the encapsulant is encapsulated between the supporting layer and the positioning member layer.

20. The method of claim 14, wherein the semiconductor chip further has a plurality of electrode pads on the active surface, and the build-up trace structure further has at least a dielectric layer, a build-up trace layer formed on the dielectric layer, a solder mask formed on the build-up trace layer, and a plurality of buried conductive vias formed in the dielectric layer and electrically connected to the build-up trace layer and the electrode pads.

21. The method of claim 20, wherein the build-up trace structure further has conductive pads exposed therefrom, and the method further comprises a step of disposing conductive elements on the conductive pads.
